(19) United States
(12) Patent Application Publication
(10) Pub. No.: US 2012/0183004 A1
(43) Pub. Date: Jul. 19, 2012

(54) Ultra-Low Frequency-Noise Semiconductor Laser With Electronic Frequency Feedback Control and Homodyne Optical Phase Demodulation

(75) Inventor: Vladimir Kupershmidt, San Francisco, CA (US)

(73) Assignee: Redfern Integrated Optics, Inc., Santa Clara, CA (US)

(21) Appl. No.: 13/325,001

(22) Filed: Dec. 13, 2011

Related U.S. Application Data
(60) Provisional application No. 61/422,624, filed on Dec. 13, 2010.

(51) Int. Cl. H01S 5/06

(52) U.S. Cl. 372/29.011

(57) ABSTRACT

The present invention provides a semiconductor laser that operates with a frequency feedback control loop for frequency-noise reduction. The frequency-reduction architecture utilizes a homodyne optical phase demodulation approach. Such phase demodulation can be implemented with help of an unbalanced Michelson interferometer with fiber optics delay and symmetrical ‘n×n’ optical coupler. The entire demodulator is packaged in a small form-factor package which doesn't have any mechanical resonance in the sensing bandwidth, and has very low sensitivity to the external acoustic or vibration induced noise sources.

### CROSS-REFERENCE TO RELATED APPLICATIONS

This application claims priority from U.S. Provisional Application Ser. No. 61/422,624, filed Dec. 13, 2010.

### FIELD OF THE INVENTION

The present invention relates generally to methods and systems of noise reduction in semiconductor lasers. Specifically, the present invention describes frequency noise reduction of semiconductor lasers with fiber-optic delay line and an optical coupler.

### BACKGROUND

Fiber-optic based sensing is used in various commercial, defense, or scientific applications, such as, fluid flow (e.g., oil or gas flow) characterization, acoustic logging, structural integrity monitoring for terrestrial or under-sea installations, subsurface visualization for geothermal energy exploration, seismic monitoring, etc.

It is known that fiber-optic interferometric sensing applications with low environmental noise floor contribution require ultra-low frequency-noise laser sources with very low sensitivity to acoustic pick-up and vibration induced noise, typically in the frequency bandwidth of up to 5-10 kHz.

It is also known in the art that certain industrial applications, such as, continuous wave (CW) coherent Doppler Light Detection and Ranging (LIDAR) and remote Laser Doppler Vibrometry (LDV), require ultra-low excess noise contribution, i.e., very narrow Lorentzian linewidth sources with linewidth below 1 kHz.

One of the widely used conventional approaches for frequency-noise reduction is electronic feedback frequency control, which is mostly used with fiber lasers and semiconductor lasers. Such a control architecture uses some type of passive optical frequency discriminator, such as, Fiber Bragg Grating (FBG), Fabry-Perot (FP) resonator, Mach-Zehnder Interferometer (MZI), Michelson Interferometer (MI), or any other type of reference-stabilized cavity to convert laser frequency noise into a voltage, followed by application of a feedback control signal for laser frequency stabilization using negative electronic feedback.

Frequency-noise reduction using a frequency control feedback requires low frequency-noise free-running laser sources. Such laser sources are developed by various companies, such as, Koheras Inc, Orbits Lightwave Inc, NP Photonics, Inc., and the current assignee, Redfern Integrated Optics, Inc. A type semiconductor external cavity laser developed and manufactured by Redfern Integrated Optics, Inc., commercially known as PLANEX, is described in the co-owned co-pending US patent application no. 2010/0303121, by Alalusi et al.

Passive optical frequency discriminators known in the art and used for frequency-noise reduction typically have a non-linear transfer function between laser frequency-noise and output of the discriminator. For the proper operation of an electronic frequency feedback loop, it is necessary to keep the laser wavelength at the discriminator slope corresponding to the “null” condition (also known as quadrature condition) by tuning some of the operating conditions of the laser, such as, bias current and temperature controlled by a thermoelectric cooler (TEC).

Such a negative feedback circuitry has a limited voltage locking range because of a laser's wavelength and power drift induced by the ambient and packaging conditions that can result in the laser frequency moving out of the quadrature condition. Conventional passive optical discriminators used in the frequency feedback control architecture do not provide any information or have very limited information on the quadrature conditions, and therefore require additional means for monitoring the quadrature condition.

Another disadvantage of optical discriminators known in the art and used in the frequency-noise reduction is a low gain (slope) of the discriminator which limits the frequency-noise reduction capability of laser sources, especially at low frequencies at the range of 1 to a few hundred hertz.

An alternative approach known in the art is to use phase generated carrier (PGC), which allows electronic feedback to operate independently of wavelength and power drift and does not require a feedback reset operation. However it has a limited frequency bandwidth, requires large amplitude of phase modulation, and a large packaging volume, which make the laser sensitive to acoustic and vibration induced noise.

Therefore what is needed is a system (and corresponding methods) that addresses the known problems in the art, and improves the frequency-noise reduction operation.

### SUMMARY OF THE INVENTION

The present invention describes an architecture for achieving ultra-low frequency-noise in lasers. The present invention provides a semiconductor laser that operates with a frequency feedback control loop for frequency-noise reduction. The frequency-reduction architecture utilizes a homodyne optical phase demodulation approach. Such phase demodulation can be implemented with help of an unbalanced Michelson interferometer with fiber-optic delay, a symmetrical ‘n×n’ optical coupler, and an integrated PD array.

The entire demodulator may be packaged in a small form-factor package which doesn't have any mechanical resonance in the sensing bandwidth range, and has very low sensitivity to the external acoustic or vibration induced noise sources.

A further aspect of the invention includes calibration of a homodyne phase detection circuit using a known reference laser source with narrow linewidth and ultra-low frequency-noise.

Yet another object of the invention is to provide a processing circuitry for a hybrid operation of an analog frequency feedback control loop augmented with a digital control.

The invention itself, together with further aspects, objects and advantages, can be better understood by persons skilled in the art in view of the following detailed description and the drawings.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1 is a schematic diagram showing various components of system used for frequency noise reduction, according to an embodiment of the present invention;

FIG. 2 show details of small form-factor package for Michelson interferometric sensing with integrated photodetector (PD) array and acoustic and vibration isolated viscoelastic enclosure, according to embodiments of the present invention;

FIG. 3 shows a graph of the experimental data of frequency noise reduction obtained from external cavity planar semiconductor laser operating with frequency feedback control circuit of the present invention;

FIG. 4A shows components of a system for characterization of a packaged optical phase demodulator with integrated PD array;

FIG. 4B shows a typical bias current profile; and,

FIG. 4C shows graphs of the results of the characterization;

FIG. 5 shows the operation of a processing circuitry that includes an analog frequency feedback control loop and digital control, according to an embodiment of the present invention; and

FIG. 6 shows a graph of frequency-noise with time, according to an embodiment of the present invention.

### DETAILED DESCRIPTION OF EXAMPLE EMBODIMENTS

The present invention will now be described in detail with reference to the drawings, which are provided as illustrative examples of the invention so as to enable those skilled in the art to practice the invention. Notably, the figures and examples below are not meant to limit the scope of the present invention to a single embodiment, but other embodiments are possible by way of interchange of some or all of the described or illustrated elements. Moreover, where certain elements of the present invention can be partially or fully implemented using known components, only those portions of such known components that are necessary for an understanding of the present invention will be described, and detailed descriptions of other portions of such known components will be omitted so as not to obscure the invention. Embodiments described as being implemented in software should not be limited thereto, but can include embodiments implemented in hardware, or combinations of software and hardware, and vice-versa, as will be apparent to those skilled in the art, unless otherwise specified herein. In the present specification, an embodiment showing a singular component should not be considered limiting; rather, the invention is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the present invention encompasses present and future known equivalents to the known components referred to herein by way of illustration.

As described in the Background section, there are growing requirements in distributed infrastructure for high resolution distributed fiber optic sensing. Distributed sensing is particularly important for detecting early signs of damage along the whole infrastructure, examples of which may be oil pipes or ocean-bottom cables (OBC) laid on the seabed that are tens of miles/kilometers long. Example applications also include downwell seismic (e.g., hydrophones and geophones) applications, downwell acoustic applications, land seismic applications, and other marine infrastructure monitoring applications. Additional possible applications may include high-resolution spectroscopy, gravitational wave detection, coherent optical communication, etc. Persons skilled in the art will appreciate that the example applications do not limit the scope of the invention in any way.

There are a few fundamental requirements for laser frequency-noise reduction architecture for highly demanding sensing applications using frequency feedback control circuitries which operate independently of slow wavelength and optical power drifts and which do not require changes in the lasers operating conditions. Some of the requirements are:

1. Specifications for frequency-noise in the frequency range from 0.1 Hz to few kHz with less than of 400 Hz/sqrt (Hz) at 1 Hz and 50 Hz/sqrt (Hz) at 100 Hz.
2. Feedback control circuitry preferably operates continuously at quadrature conditions in the changing ambient temperature environments (−10° C. to 70° C.) without any interruption on feedback reset (i.e. a reset-free operation is preferred).
3. Any error correction applied to the laser control circuitry (e.g., thermoelectric cooler temperature and bias current) via a negative feedback should not exceed the laser operating margin.
4. Robust packaging is required with very low sensitivity to external disturbances such as acoustic pick-up and vibration induced noise.

Embodiments of the present invention address these and other requirements. The specific ranges and numbers described throughout the specification are for illustrative purposes only, and they do not necessarily limit the scope of the present invention.

The present invention describes frequency stabilization circuitry operating with various types of lasers. Types of lasers may include Distributed Feedback (DFB) lasers and external cavity lasers (ECL). An example of the semiconductor type ECL is the PLANEX-type semiconductor external cavity laser manufactured by Redfern Integrated Optics, Inc.

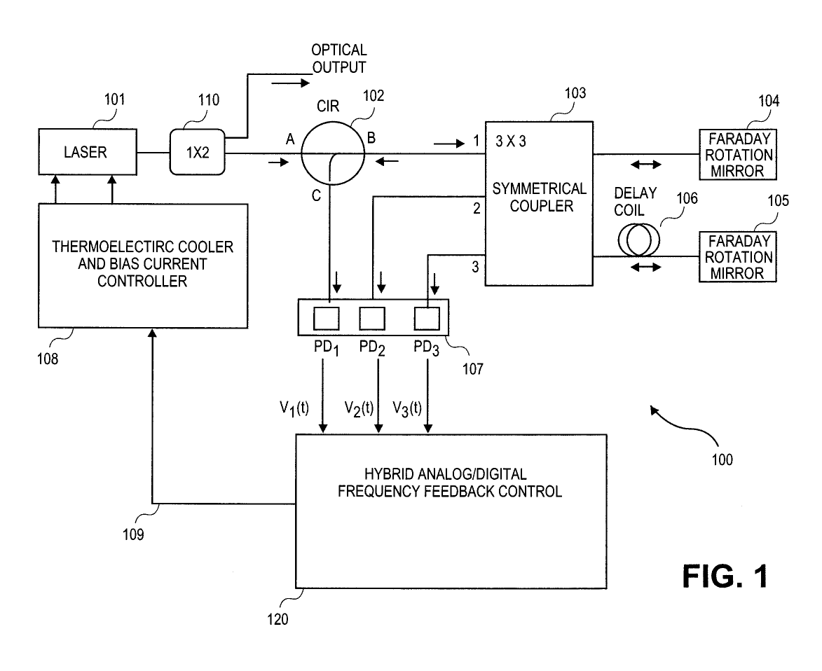

One of the objects of the present invention is to provide a semiconductor laser that operates with a frequency feedback control loop for frequency-noise reduction. Semiconductor lasers with frequency feedback control may utilize a homodyne optical phase demodulation approach. Such phase demodulation can be implemented with help of an unbalanced Michelson interferometer with fiber optics delay and symmetrical ‘n×n’ optical coupler, where ‘n’ is an integer. For example, FIG. 1 shows a 3×3 symmetrical optical coupler.

Homodyne phase demodulation does not require maintaining a quadrature conditions and is not affected by the laser wavelength drift. As a result, it is possible to decouple the signal of interest (proportional to the laser frequency-noise) from the signal drift without the concern of maintaining the quadrature conditions. This enables a continuous reset-free operation of the semiconductor laser.

A further object of the invention is to utilize unique properties of a free-running semiconductor external cavity laser that has very-low frequency-noise as a start. The frequency stabilization circuitry has the ability to provide electronic feedback to the bias current. Such combination is unique and is necessary to achieve frequency-noise reduction to ultra-low levels.

Another object of the invention is to provide frequency-noise reduction of free running semiconductor external cavity lasers operating with a frequency feedback control loop using single pass optical delay (t). The delay may be of the order of 5-10 meters (25 to 50 nsec). Such optical delay provides a high gain to the optical frequency discriminator which is necessary to achieve ultra-low frequency-noise.

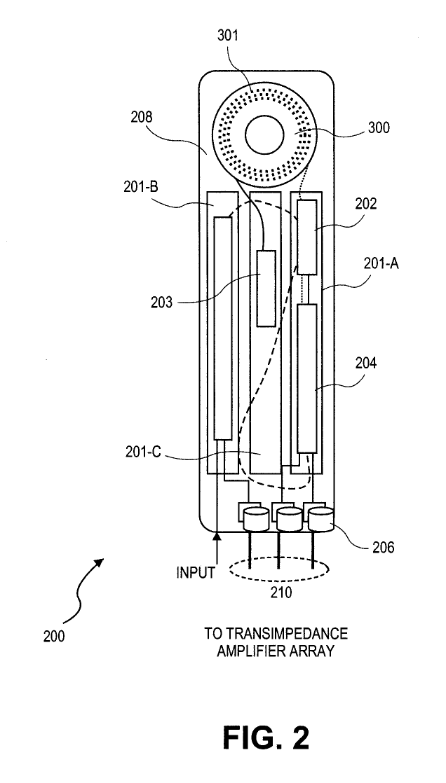

Another object of the invention is to provide a small form-factor package of a Michelson Interferometer (MI) optical phase demodulator with integrated photodiode (PD) array (shown in FIG. 2) operating in typical conditions required for sensing applications.

Another object of the invention is to provide a calibration algorithm for calibrating an assembled and packaged optical phase demodulator with integrated PD array. Such calibration based on the unique properties of a planar semiconductor external cavity laser has a very low dc-chirp (δν/δI) in response to the change in the bias current ‘I’. Such a calibration approach results in the complete calibration of the assembled and packaged optical phase demodulator and takes into account all of the manufacturing-related differences and variations associated with different gains of the PD array, coupling and splicing losses, and phase offsets between different branches of the symmetrical 3×3 optical coupler.

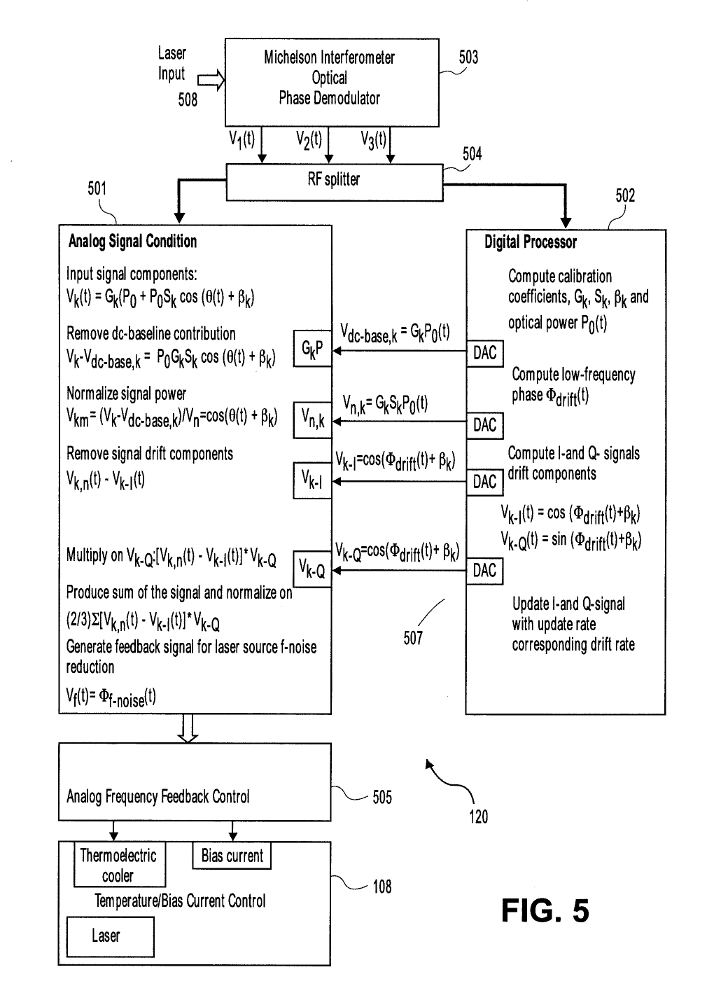

Another object of the invention is to provide a processing circuitry (shown in FIG. 5) for hybrid operation of an analog frequency feedback control loop and digital control. In such a circuit, outputs of a photodiode array of the phase demodulator is split into analog and digital outputs, where the analog output is used for the fast analog feedback control circuitry, while a low bandwidth (for example bandwidth <100 Hz) digital circuitry (with digital signal processor DSP or micro-processor) provides the signal components for normalization on optical power, dc-baseline subtraction and information on slow time varying phase drift conditions. Such an approach allows to compensate for the effect of the baseline variations, such as, optical power, intensity noise and sub-hertz phase drift variations.

The elements of the FIGS. 1-6 are described in greater detail below.

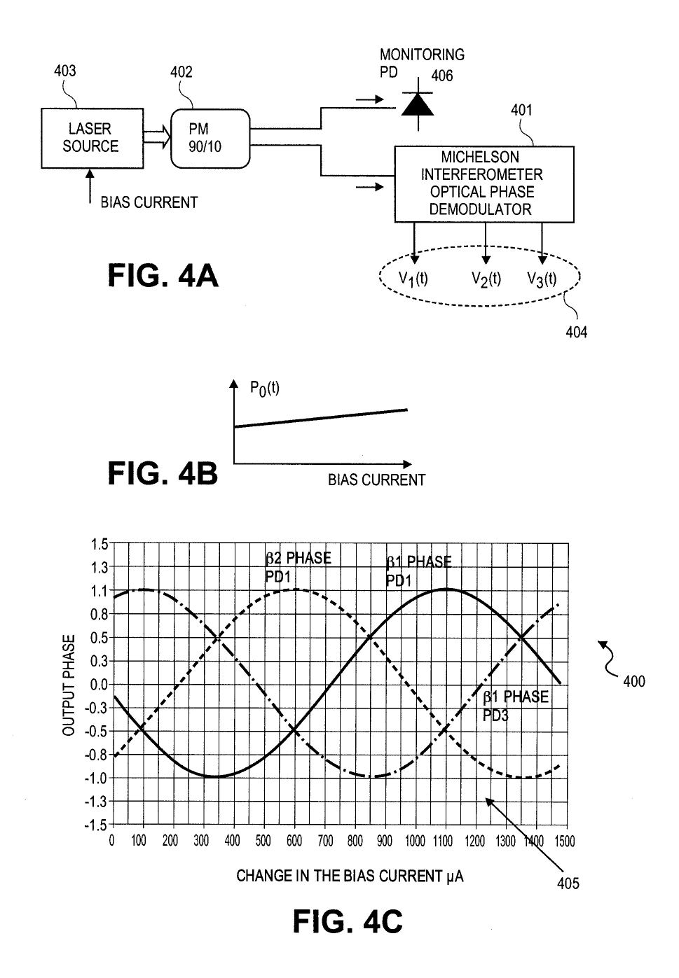

FIG. 1 shows details of the operation of ultra-low noise semiconductor laser with hybrid analog/digital frequency feedback control using Michelson interferometer with fiber optic delay, symmetrical 3×3 coupler, and integrated PD array, which function as homodyne phase demodulator. Persons skilled in the art will recognize that elements 102, 103, 104, 105 and 107 of FIG. 1 are combined into element 503 in FIG. 5, and element 401 in FIG. 4A. The functional blocks shown in FIGS. 1, 4A and 5 are shown for illustrative purposes only. More blocks may be added, some blocks may be deleted, some blocks may be combined/functionally separated, depending on the end goal and application.

Referring back to FIG. 1, a system 100 is illustrated for frequency noise reduction using the frequency feedback control with homodyne optical phase demodulator. System 100 incorporates the principles of the present invention. System 100 includes a source laser 101 which is coupled into a polarization-maintaining (PM) 1×2 splitter 110. The splitting ratio may be in the range of 5/90-10/90, i.e., a small portion (5-10%) of the laser's optical power is coupled via an optical circulator 102 (with input ports A and B, and output post C) into an unbalanced Michelson interferometer (MI), and the rest goes to another optical output path. The Michelson interferometer has at its input (port 1) a symmetrical 3×3 coupler 103 and two optical branches terminating at corresponding Faraday Rotation Mirrors (FRM) 104 and 105. One of the branches has an optical delay coil 106. Laser light launching into MI is split and propagates down the optical paths of the two optical branches. The FRMs 104 and 105 are necessary to prevent interferometric polarization fading.

The laser light launched into the optical branches experience a double propagating path upon the reflection from FRMs 104 and 105, and propagates back via the output port C of optical circulator 102 and output ports 2 and 3 of the symmetrical 3×3 couple 103. Each outputs via output ports C, 2, and 3 represents interferometric beating of two optical fields.

Using the optical circulator 102 in combination with the 3×3 coupler allows minimization of optical losses in one output and equalizes optical power distribution between the coupler's outputs 2 and 3. The three outputs C, 2,3 provide baseband phase information (homodyne phase demodulation) that is necessary for operation of the frequency feedback control loop. Each of the optical outputs is coupled into PD array 107 having high gain trans-impedance amplifiers (TIAs—not shown specifically), which results in three analog voltage outputs V₁(t), V₂(t), V₃(t).

The general form of voltage output is:

Vₖ(t)=GₖP₀(t)(1+Sₖ cos(θ(t)+βₖ)),k=1,2,3 (1)

where Gₖ is a cumulative voltage gain of MI demodulator, accounting for all optical losses and coupling, PD gain, TIA amplifications, etc; P₀(t) is a optical power launched into MI demodulator; Sₖ<1 is k-channel interferometer visibility; βₖ is a relative phase shift between outputs of symmetrical 3×3 couplers, which in ideal situations are 0, 120, 240 degree, while δₖ is their deviations from theoretical values θ(t), which is given by:

θ(t)=Φ_{f-noise}(t)+Φ_{drift}(t) (2)

Φ_{f-noise}(t) is a frequency noise of laser Φ_{drift}(t) is a slow (sub-hertz frequency range) stress and temperature induced drift. θ(t) is a cumulative phase of MI demodulator.

Homodyne phase demodulation allows to separate slow changing voltage output V_{drift} from V_{f}(t). V_{drift} is a signal proportional to the phase drift Φ_{drift}(t); V_{f}(t) is a signal proportional to the frequency noise Φ_{f-noise}(t).

Voltage outputs from the PD array 107 are amplified using trans-impedance amplifier array, TIA (not shown) RF split by the RF splitter and directed to the analog and digital portion (using low frequency high resolution analog to digital converters, ADC) of hybrid analog and digital frequency feedback control unit 120. Functionalities and operation of feedback control unit 120 will be describe below with references to the FIG. 5.

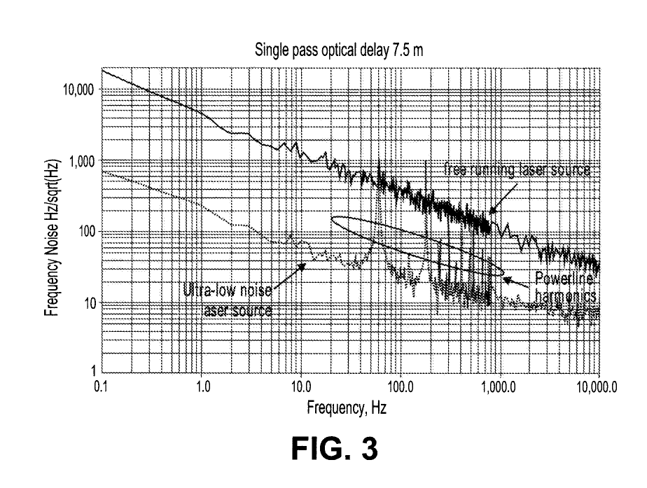

The frequency feedback control unit 120 generates a temperature and bias current negative error signals 109 which are supplied to the laser thermoelectric cooler (TEC) and bias current control unit 108. As a result, the closed loop of such operation considerably reduces frequency-noise compared to that of a free running laser. FIG. 3 shows experimental results of frequency-noise reduction based on present invention. Experimental results have demonstrated large frequency noise reduction by ˜16 times (12 dB) (1 Hz to 100 Hz) in the frequency range up to 10 kHz, for a single pass optical delay of 7.5 m. The results are obtained from a PLANEX-type semiconductor laser manufactured by Redfern Integrated Optics, Inc.

FIG. 2 shows how to design and package optical homodyne phase demodulator comprising of FRM, optical circulator, 3×3 coupler and optical delay coil in a small form-factor package. Some design requirements for a specific example embodiment are described below.

One of the requirements is that there should be no mechanical resonances in the sensing bandwidth of 10 kHz over environmental temperature −10° C. to 70° C. The whole package must behave as an “isolator” in response to the external disturbances caused by the acoustic and vibration sources present in the sensing applications. Such requirements demand that the package design have a small form-factor with no relative movement of fiber-optic components. Specifically the package should have no acoustic-pickup of the optical delay coil and no/minimal sensitivity to fiber-leads. To address such requirements, one specific embodiment of the present invention uses fiber optic components and a fiber coil made from high NA ultra-low profile bend-insensitive single mode fiber with very low cladding diameter of 50 μm and acrylic coating of 110 μm, manufactured by FiberCore, Ltd, UK. The fiber is used in the form of a small diameter acoustic hydrophone coil. Such fiber results in very small bending radius of all fiber optic components used in the Michelson phase demodulator, such as, the FRMs 104 and 105, the 3×3 coupler 103, and the circulator 102.

The fiber delay coil 106 made from such fiber uses high elastic modulus (e.g., E=114-120 GPa) solid coilform 300 made from the titanium alloy with the diameter of 10 mm and height of 3 mm and able to accommodate winding fiber of 5 to 10 meters without any bending attenuation.

The package 200 package with acoustic and vibration-isolated viscoelastic enclosure behaves as an “isolator”, i.e. doesn't have any mechanical resonance in the sensing bandwidth of up to 15 kHz, and has very low sensitivity to the external acoustic or vibration induced noise sources. To secure winding fiber layers to a coilform, one example embodiment uses a high elastic modulus (E=11 GPa) winding encapsulant, produced by EPO-TEK, Inc. or Bacon Industries, Inc.

In the package 200, the 3×3 coupler 204, FRMs 202 and 203 and optical circulator 205 and fiber delay coil 301 wound on the titanium alloy coilform 300 are all disposed in close proximity. All of the components are aligned and secured in the individual grooves 201-A, 201-b, 201-C, and 201-D made within a molded enclosure 208 made from, for example, viscoelastic Sorbothane material (manufactured by Sorbothane Inc) with a high degree of acoustic and vibration isolation. To increase acoustic and vibration isolation and avoid temperature induced stress, all optical components may be immersed into a gel, such as, dielectric silicone gel Q3 6575 manufactured by Dow Corning, which will remain in the gel form over a wide ambient temperature range. Finally, within the same Sorbothane enclosure all three fiber optic outputs of Michelson phase demodulator are coupled (pigtailed) to the PD array 206. As a result package 200 has one optical Input and three electrical leads 210 for following electrical connections to the TIA array.

Persons skilled in the art will appreciate that other types of packages and packaging materials may be used too without diverting from the scope of the invention.

FIG. 4A shows components of a system for characterization/calibration of packaged optical phase demodulator with integrated PD array. FIG. 4B shows typical bias current profile. FIG. 4C illustrates results 400 from calibration of Michelson homodyne phase demodulator.

Operation of the frequency feedback control loop requires calibration of voltage output signals in a certain form. In an example embodiment, such calibration can be done using the unique properties of the PLANEX-type laser which has very low dc-frequency chirp δν/δI in response to the change in a bias current. Calibration approach of present invention results in complete characterization of assembled and packaged Michelson phase demodulator and allows considerable reduction in production cost.

In the calibration set-up, a PLANEX-type laser source 403 (or any other narrow linewidth low-noise laser source) is directly couple into Michelson phase demodulator 401 using polarization maintaining (PM) coupler 402 with split ratio between 5 to 10%. Main channel of optical output is routed for optical power monitoring with monitoring photodiode 406, while the other channel goes to the MI optical phase demodulator 401. Voltage outputs 404 from MI phase demodulator 401 can be presented in the form of equation (1). Calibration of the MI phase demodulator requires a linear change in the bias current applied to the laser source 403. Typical values of the bias current may be 1.5-2 mA. Since the dc-chirp of PLANEX-type laser is very low (of the order of 8-12 MHz/mA), it is possible to use a step resolution of 8-12 μA and produce ˜150 measurements points on the digitized voltage waveforms.

The amplitude of the applied linear swing of bias current is chosen from the conditions that each voltage waveform change during a linear current swing over a complete period of cos-waveforms 405. Each cos-waveform has a relative phase shift between them corresponding to the actual phase shift between outputs of the 3×3 coupler βₖ. Digitizing outputs of cos-waveforms of voltage outputs allows to produce a full set of calibration coefficients of Michelson phase demodulator.

Relative phase shift between waveforms=βₖ.

Gₖ=(V_{k,max}+V_{k,min})/2P₀

Sₖ=(V_{k,max}−V_{k,min})/(V_{k,max}+V_{k,min}) (3)

where P₀(t) is a monitoring power measured by the PD 406, V_{k,max and} V_{k,min} are the maximum and minimum voltages of digitized cos-waveforms representing the voltage outputs 404.

FIG. 5 shows a detail of processing algorithm for operation of hybrid analog frequency feedback control loop and digital control circuitry. As described before with respect to FIG. 1, the unit 120 controls the hybrid operation of analog frequency feedback control loop and low-frequency digital processing. In such approach the digital processor “removes” slow time-varying drift signal (sub-hertz) from the voltage output of Michelson Interferometric frequency discriminator, while electronic frequency feedback suppresses only the “high” optical frequency noise in the bandwidth of, for example, 1 to 10 kHz. As a result, there is no need to maintain quadrature conditions for the operation of the frequency feedback loop.

In FIG. 5, laser input 508 (i.e. input laser beam) is coupled to the Michelson optical phase demodulator 503, which produces at its output voltage signals V₁(t), V₂(t), and V₃(t). The voltage outputs are split by the RF splitter 504 and directed to analog signal conditioning circuitry 501 and digital processing circuitry 502. The digital processing circuitry may comprise a micro-processor (μ-P) or digital signal processor chip (DSP).

The digital processing circuitry 502 has built-in a calibration table with all calibration coefficients Gₖ, Sₖ and βₖ obtained from the calibration process described with respect to FIGS. 4A-4C. Using such calibration coefficients, trigonometric manipulations and a standard phase un-wrapping algorithm, known in the signal processing art, a set of slow-changing phase demodulated signals are obtained (with rate corresponds to the drift rate). The signals are expressed as:

P₀(t)

P₀(t)cos(Φ_{drift}(t)),

and

P₀(t)sin(Φ_{drift}(t)) (4).

Next, digital signal processor 502 using set of high resolution digital to analog converters (DAC) directs the following signals 507 to the analog signal conditioning circuitry 501:

dc-baseline voltage: V_{dc-base,k}=GₖP₀(t)

normalization voltage: V_{n,k}=GₖSₖP₀(t)

dc-drift voltages: Vₖ₋₁(t)=cos(Φ_{drift}(t)+βₖ)

V_{k-Q}(t)=sin(Φ_{drift}(t)+βₖ) (5)

Using analog subtraction and division (known in the art and implemented in discrete circuitries) analog signal conditioning circuitry 501 generates the following “normalized” voltage signals:

V_{k,n}(t)=−Φ_{f-noise}(t)V_{k-Q}(t) (6)

Next, signal V_{k,n}(t) is analog multiplied (using known discrete circuitries) on the corresponding signal ⅔*V_{k-Q}(t) provided by a digital processor 502 to produce:

V_{k,n}(t)*V_{k-Q}(t)=−Φ_{f-noise}(t)*(⅔)[V_{k-Q}(t)]² (7)

After such multiplication, corresponding channel signal are summed using analog summing circuitry to produce signal in the following form:

V_{f}(t)=−Φ_{f-noise}(t)Σ(⅔)*[V_{k-Q}(t)]² (8)

In all practical situations, sum of the voltage signals over all channels of phase demodulator is close to 1, i.e. it can be expressed as:

(⅔)Σ[V_{k-Q}(t)]²≈1 (9)

After all the analog operations, analog signal conditioning circuitry 501 generates amplified voltage signal V_{f}(t) representing laser frequency-noise signal, which is directed to the analog frequency feedback control unit 505.

V_{f}(t)=−Φ_{f-noise}(t) (10)

V_{f}(t) is an analog voltage signal proportional to the laser frequency noise Φ_{f-noise}.

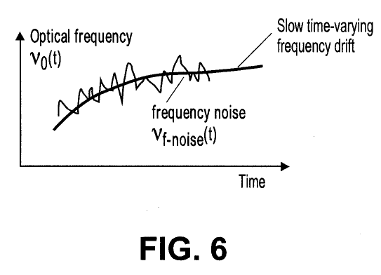

Finally, the frequency feedback control unit 505 with network phase compensation generates correction signals to be fed to the laser TEC and bias current, as controlled by the ultra-low noise controller 108. This results in ultra-low frequency noise operations of semiconductor laser. During the close loop continuous operations, the digital processor 502 constantly updates (using forward prediction algorithms know in the art of digital processing) all slowly time varying parameters, such as P₀(t), V_{k-I}(t), V_{k-Q}(t) with an update rate corresponding to the drift rate in the system (typically in the sub-hertz range). FIG. 6 illustrates the results of an effective operation of the electronic frequency feedback control with homodyne phase demodulation, where the frequency noise is demonstrated to follow the slow time-varying frequency drift.

The descriptions above are intended to be illustrative, not limiting. Thus, it will be apparent to one skilled in the art that modifications may be made to the invention as described without departing from the scope of the claims set out below.

What is claimed is:

1. A system for reducing a frequency-noise of a semiconductor laser, the system comprising:
a semiconductor laser with a narrow linewidth;
a fiber-optic unbalanced interferometric circuit coupled to the semiconductor laser via an optical circulator;
a photodiode (PD) array for generating homodyne optical phase demodulated voltage signals from back-propagating optical output signals received from the fiber-optic unbalanced interferometric circuit;
a hybrid analog and digital frequency feedback control circuit; and
a laser controller circuit that receives an electronic signal from the frequency feedback control circuit to control operating parameters of the semiconductor laser, thereby reducing frequency-noise of the semiconductor laser.

2. The system of claim 1, wherein the fiber-optic unbalanced interferometric circuit comprises:
a 3×3 symmetrical coupler;
a first optical path with a first length, terminating at a first Faraday Rotation Mirror (FRM); and
a second optical path with a second length different from the first length to introduce a predetermined amount of delay, the second optical path terminating at a second FRM.

3. The system of claim 2, wherein the predetermined amount of delay is introduced by a fiber-optic delay coil.

4. The system of claim 3, wherein one back-propagating optical output signal coming out of the 3×3 symmetrical coupler is routed to the PD array via the circulator, and two back-propagating optical output signals are routed directly to the PD array, each of the three back-propagating optical output signals representing interferometric beating of two optical fields from the first optical path and the second optical path.

5. The system of claim 4, wherein the PD array outputs three analog voltage signals containing homodyne optical phase demodulation information.

6. The system of claim 5, wherein the three analog voltage signals outputted by the PD array are amplified and split into an analog component and a digital component by a radio frequency (RF) splitter, wherein an analog signal conditioning unit receives the analog component of the voltage signals, and a digital signal processor receives the digital component of the voltage signals, both the analog signal conditioning unit and the digital signal processor being included in the hybrid analog and digital frequency feedback control circuit.

7. The system of claim 6, wherein the analog component of the voltage signals are conditioned at the analog signal conditioning unit using digital-to-analog converted signals received from the digital signal processor.

8. The system of claim 7, wherein the analog signal conditioning unit produces an output analog signal proportional to a frequency-noise of the semiconductor laser, the output analog signal being received by the laser controller circuit as the electronic signal that controls the operating parameters of the semiconductor laser.

9. The system of claim 8, wherein the operating parameters of the semiconductor laser include temperature of a thermoelectric cooler (TEC) and bias current.

10. The system of claim 1, wherein the fiber-optic unbalanced interferometric circuit, the circulator, and the PD array are packaged in a small form-factor package.

11. The system of claim 10, wherein a delay coil included in the fiber-optic unbalanced interferometric circuit is supported by a solid coilform encapsulated within the package, the coilform having a high elastic modulus.

12. The system of claim 11, wherein the delay coil comprises nigh numerical aperture (NA) bend-insensitive fiber.

13. The system of claim 10, wherein the package is made of viscoelastic material for vibration isolation in a sensing bandwidth and prevention of acoustic pick-up.

14. The system of claim 10, wherein the package comprises one input and three output leads, the three output leads configured to connect the integrated PD array to a trans-impedance amplifier array.

15. The system of claim 10, wherein the fiber-optic unbalanced interferometric circuit, the circulator, and the PD array packaged in the small form-factor package is calibrated with a laser source with known ultra-low frequency-noise.

16. The system of claim 15, wherein the known ultra-low frequency-noise laser source is a semiconductor external cavity laser with planar Bragg gratings.

17. The system of claim 15, wherein the calibration takes into account manufacturing differences, variations associated with different gains of the PD array, coupling and splicing losses, and optical phase offsets between different branches of the 3×3 coupler.

18. The system of claim 6, wherein the digital signal processor includes calibration data including calibration coefficients, trigonometric manipulations, and phase un-wrapping algorithm.

19. The system of claim 6, wherein the digital signal processor constantly updates parameters slowly varying in time with an update rate corresponding to frequency drift rate of the system.

20. The system of claim 1, wherein optical splitters used in the system maintain polarization of light.
